(19) United States
(12) Patent Application Publication
(10) Pub. No.: US 2003/0116188 A1
(43) Pub. Date: Jun. 26, 2003

(54) Solar fan

(76) Inventor: Hsin-Mao Hsieh, Pingtung City (TW)

Correspondence Address: BACON & THOMAS, PLLC, 625 SLATERS LANE, FOURTH FLOOR, ALEXANDRIA, VA, 22314

(21) Appl. No.: 10/022,347

(22) Filed: Dec. 20, 2001

(51) Int. Cl. H01L 31/00

(52) U.S. Cl. 136/291; 136/244

(57) ABSTRACT

A solar fan is disclosed. The solar fan includes a main body having an electric fan inside, and a plurality of solar cell arrays pivotally connected to the main body. Each of the solar cell arrays is pivotal between an outspread position and a folded position relative to the main body. A retainer is provided for holding the solar cell array in the outspread position. In addition, the solar cell arrays are electrically connected to the electric fan so as to supply power to the fan when being in sunlight.

### BACKGROUND OF THE INVENTION

1. Field of the Invention

The present invention relates to a fan and, more particularly, to a solar fan which is used on sites far from any electric power supply.

2. Description of Related Art

In the summer, electric fans can produce breezes which make people feel comfortable. As these fans are worked by electricity, they can be used only in places where an electric power supply is available, but not on sites far from the power supply, such as on beaches, isolated islands or the like.

Even though battery-powered fans are available, they are generally small in size and produce weak breezes. Such fans cannot work continuously for a long period due to the charge capacities of the dry batteries, which, as well known, may quickly run down and need to be replaced time to time. Electricity from dry battery is expensive and the waste batteries will contaminate the environment.

Therefore, it is an objective of the invention to provide a solar fan to mitigate and/or obviate the aforementioned problems.

### SUMMARY OF THE INVENTION

The object of the present invention is to provide a solar fan which is used on sites far from any electric power supply.

Other objects, advantages and novel features of the invention will become more apparent from the following detailed description when taken in conjunction with the accompanying drawings.

### BRIEF DESCRIPTION OF THE DRAWINGS

FIG. 1 is a perspective view of a preferred embodiment of a solar fan in accordance with the present invention, showing a plurality of solar cell arrays in outspread positions;

FIG. 2 is a front view of the solar fan of FIG. 1, showing the solar cell arrays in their outspread positions;

FIG. 3 is a front view of the solar fan of FIG. 1, showing the solar cell arrays in their folded positions;

FIG. 4 is a perspective view of an alternative embodiment of the solar fan in accordance with the present invention, showing a plurality of solar cell arrays in outspread positions;

FIG. 5 is a front view of the solar fan of FIG. 4, showing the solar cell arrays in their outspread positions; and

FIG. 6 is a front view of the solar fan of FIG. 4, showing the solar cell arrays in their folded positions.

### DETAILED DESCRIPTION OF THE PREFERRED EMBODIMENT

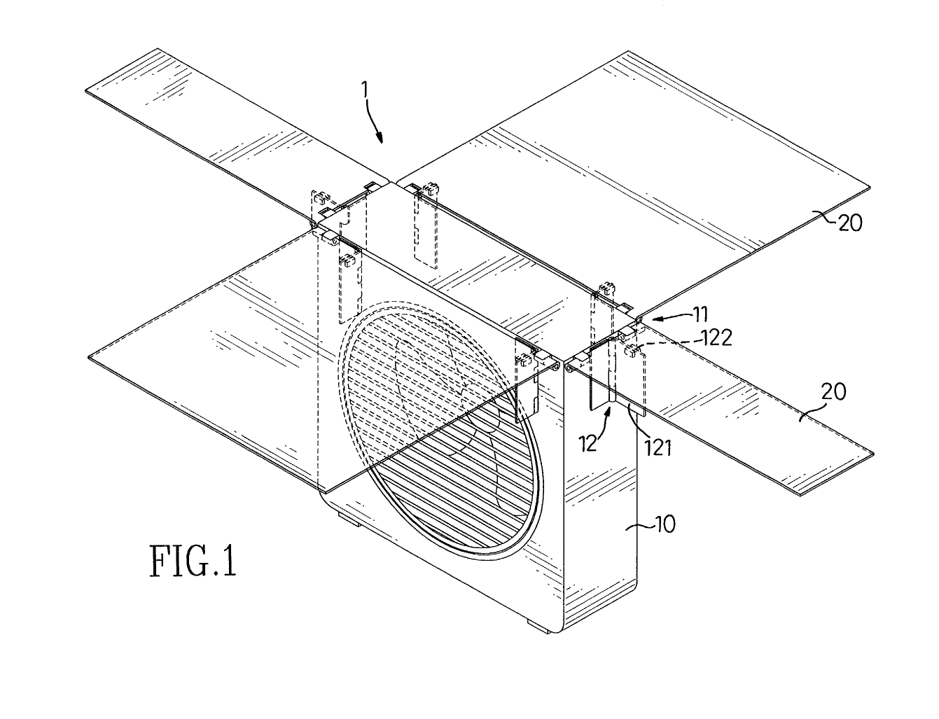

Referring to FIGS. 1 to 3, a preferred embodiment of a solar fan (1) in accordance in the present invention includes a main body (10) having an electric fan (not numbered) inside, with a plurality of solar cell arrays (20) pivotally connected to the main body (10).

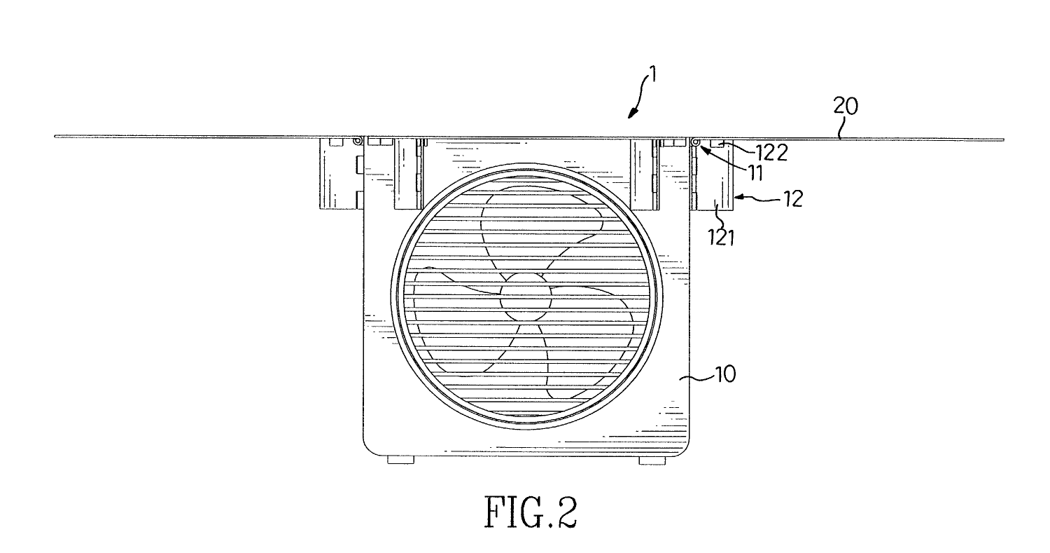

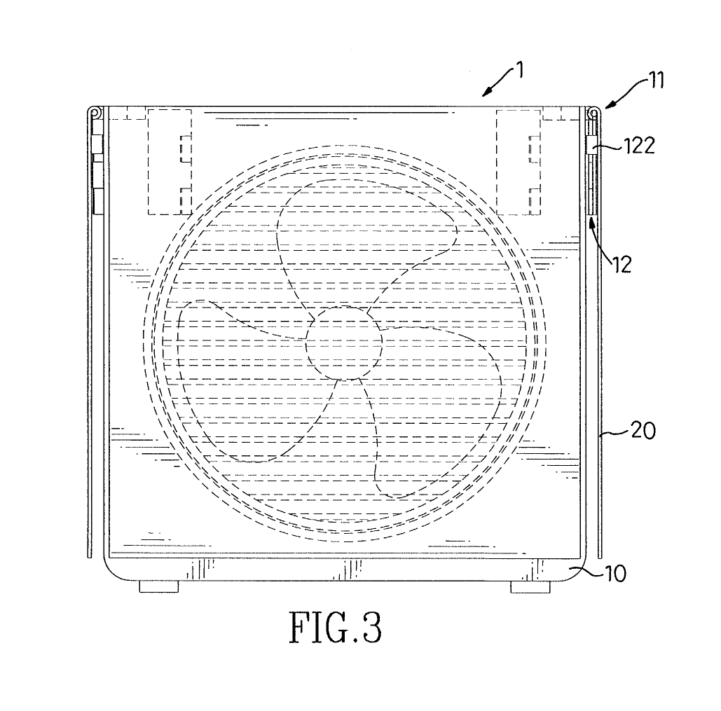

Each of the solar cell arrays (20) is pivotal between an outspread position, as shown in FIGS. 1 and 2, and a folded position, as shown in FIG. 3, about its axis (11) adjacent to a top edge of the body (10).

There is further provided a plurality of retainers (12) for holding the solar cell arrays (20) in the outspread positions.

These retainers (12) may be provided in many ways, for example, each solar cell array (20) may have a pair of slightly spaced appendages (122) formed in a bottom thereof, while the retainers (12) may each be configured as a leaf (121) pivotally connected to the main body (10). Furthermore, the leaves (121) are adapted to extend between respective two appendages (121) of the solar cell arrays (20), thereby holding the arrays (20) in their outspread positions.

The solar cell arrays (20) are electrically connected to the electric fan directly or indirectly through a rechargeable battery, in order to supply power to the fan when being in sunlight.

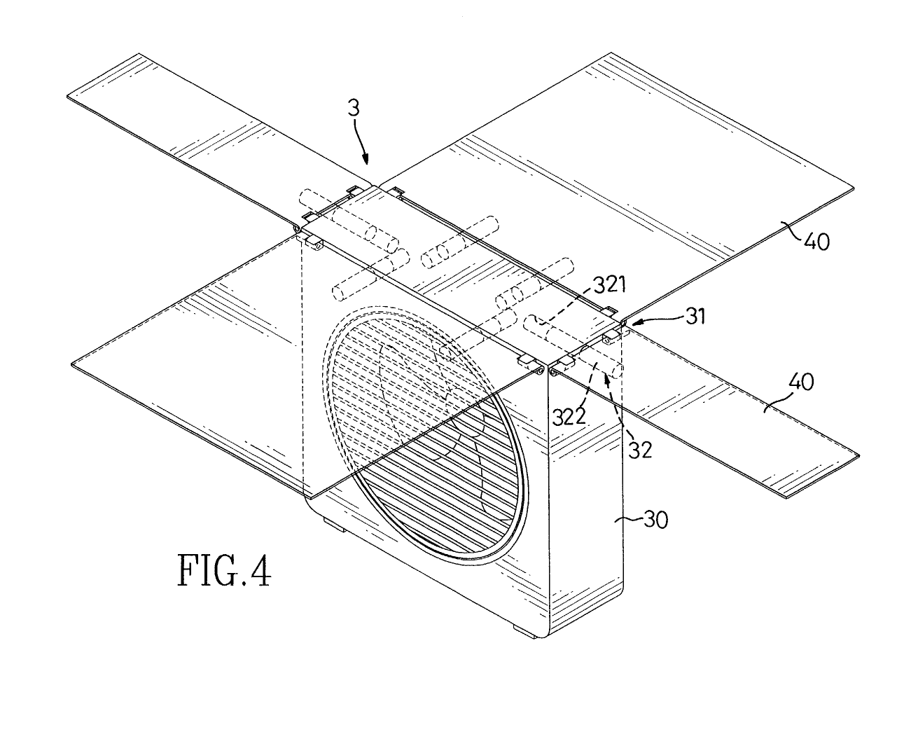

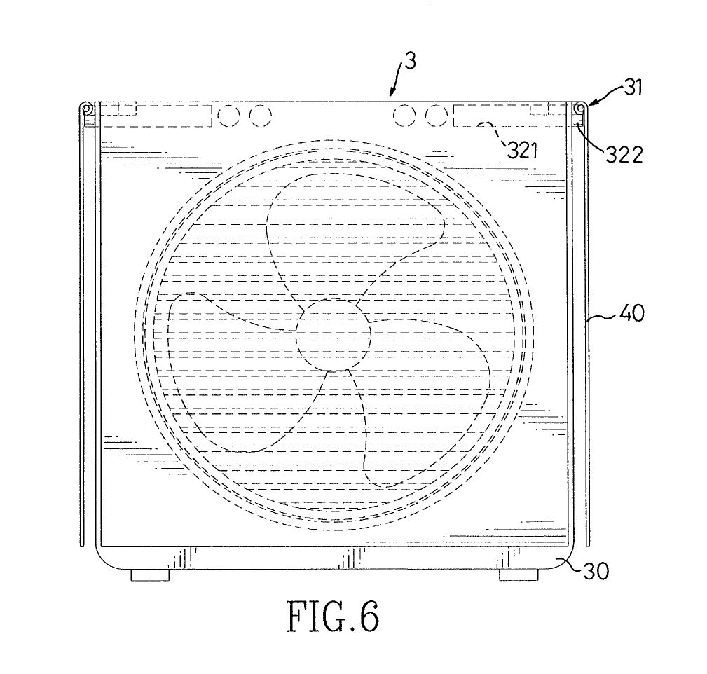

Referring to FIGS. 4 to 6, there is shown an alternative embodiment of a solar fan (3) in accordance with the present invention. This solar fan (3) also includes a main body (30) and a plurality of solar cell arrays (40) which are pivotal about respective axes (31) adjacent to top edges of the body (30).

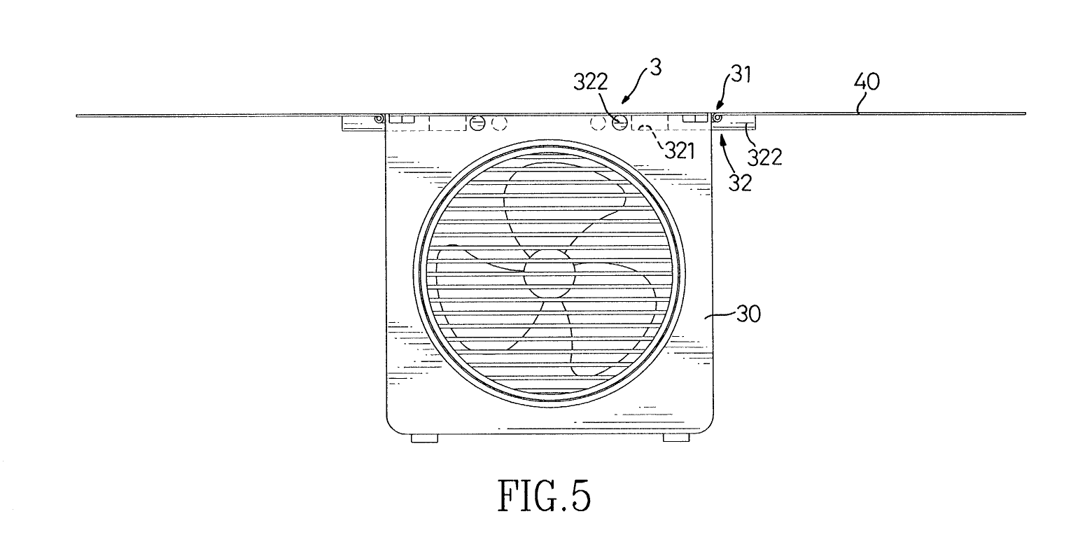

However, the main body (30) is formed with a plurality of chambers (321) immediately below the axes (31) for receiving a plurality of retainers (32) which are now configured as rods (322). These rods (322) are slidable out of the chambers (321) to support the solar cell arrays (40), as best shown in FIG. 5, thereby holding the arrays (40) in their outspread positions.

From the above description, it is noted that the invention has the advantage of being used on a site far from electric power supply.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A solar fan (1) comprising:
a main body (10, 30) having an electric fan inside;
at least one solar cell array (20, 40) pivotally connected to said main body (10, 30), said solar cell array (20, 40) being pivotal between an outspread position and a folded position relative to said main body (10, 30);
a retainer (12, 32) for holding said solar cell array (20, 40) in said outspread position; and
wherein said solar cell array (20, 40) is so electrically connected to said electric fan as to supply power to said fan when being in sunlight.

2. The solar fan as claimed in claim 1, wherein said solar cell array (20) has a pair of slightly spaced appendages (122) formed in a bottom thereof, and wherein said retainer (12) is configured as a leaf (121) pivotally connected to said main body (10) and adapted to extend between said appendages (122), thereby holding said solar cell array (20) in said outspread position.

3. The solar fan as claimed in claim 1, wherein said main body (10) is formed with a chamber (321), and wherein said retainer (322) is configured as a rod (322) slidable out of said chamber (321) and adapted to support said solar cell array (40), thereby holding said solar cell array (40) in said outspread position.
